(19) United States
(12) Patent Application Publication
(10) Pub. No.: US 2006/0124975 A1
(43) Pub. Date: Jun. 15, 2006

(54) Dual work function gate in CMOS device

(75) Inventor: Mohammed A. Fathimulla, Ellicott City, MD (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/008,435

(22) Filed: Dec. 9, 2004

(51) Int. Cl. H01L 29/76; H01L 29/94; H01L 31/062; H01L 31/113; H01L 31/119

(52) U.S. Cl. 257/288

(57) ABSTRACT

A transistor has a first silicon layer comprising a source region and a drain region separated by a channel region. A gate oxide is formed over the first silicon layer. A second silicon layer is formed over the gate oxide and comprises a dual work function gate. The dual work function gate may include p+ and n+ gate regions such that the transistor has different threshold voltages.

### FIELD OF THE INVENTION

The present invention generally relates to integrated circuit fabrication, and more particularly to an integrated circuit device having a dual work function gate.

### BACKGROUND OF THE INVENTION

In a conventional metal oxide semiconductor (MOS) transistor 10 shown in FIG. 1, (which may be alternatively a double-diffused metal oxide semiconductor (DMOS) transistor, a silicon layer 12 is doped to form a source region 14 and a drain region 16 separated by a channel region 18. A gate oxide 20 is deposited over the channel region 18. The gate oxide 20 is typically formed either by thermal oxidation of silicon or by low pressure chemical vapor deposition (LPCVD). A gate 22 is formed by suitably depositing a silicon layer 24, such as a polysilicon layer, over the gate oxide 20. The transistor 10 may also include a buried oxide layer 26 over a silicon wafer 28, as desired. The gate oxide is typically formed either by a combination of thermal and local oxidation of silicon (LOCOS) or by low pressure chemical vapor deposition (LPCVD).

The breakdown voltage of the transistor 10 depends upon the doping of the source region 14 and the drain region 16. The thickness of the gate oxide 20 is also used to control the breakdown voltage of the transistor 10 such that the thickness of the gate oxide 20 is increased in order to increase the breakdown voltage of the transistor 10. The breakdown voltage of the transistor can be increased by alternatively using the double-diffused metal oxide semiconductor (DMOS) transistor shown in FIG. 2.

FIG. 2 shows a transistor 40 having a gate 32, a gate oxide 30, a source region 34, a drain region 36, and a channel region 38. The alignment between the gate 32, the gate oxide 30, the source region 34, the drain region 36, and the channel region 38 is critical to the proper operation of the transistor 40. That is, unless the gate 32 and the gate oxide 30 are properly aligned over the channel region 38 and between the source region 34 and the drain region 36, the predetermined breakdown voltage of the transistor 40 is not achieved. Therefore, the transistor 40 will not turn on and off as desired.

Furthermore, the transistor 40 has only a single threshold voltage and, therefore, cannot be easily used in applications requiring selective multiple turn on and turn off voltages.

The present invention overcomes one or more of these disadvantages.

### SUMMARY OF THE INVENTION

In accordance with one aspect of the present invention, a transistor comprises first and second silicon layers and a gate oxide. The first silicon layer has a source region and a drain region separated by a channel region. The gate oxide is formed over the first silicon layer. The second silicon layer is formed over the gate oxide, and the second silicon layer includes a dual work function gate.

In accordance with another aspect of the present invention, a semiconductor device comprises first and second silicon layers and a gate oxide. The first silicon layer has first and second electrodes formed therein. The gate oxide is formed over the first silicon layer. The second silicon layer is formed over the gate oxide, and the second silicon layer comprises a dual work function gate.

In accordance with yet another aspect of the present invention, a method of making a transistor comprises the following: forming a buried oxide layer over a first silicon layer; forming a second silicon layer over the buried oxide layer such that the second silicon layer includes a source region and a drain region separated by a channel region; forming a gate oxide formed over the channel region of the second silicon layer; and, forming a third silicon layer over the gate oxide such that the third silicon layer includes a dual work function gate.

### BRIEF DESCRIPTION OF THE DRAWINGS

These and other features and advantages will become more apparent from a detailed consideration of the invention when taken in conjunction with the drawings in which:

FIG. 1 is a cross section of a semiconductor device according to the prior art; and,

FIG. 2 is a cross section of a LDMOS device according to the prior art;

FIG. 3 is a cross section of a semiconductor device according to the present invention; and,

FIG. 4 shows a silicide region over the gate of the semiconductor device shown in FIG. 3.

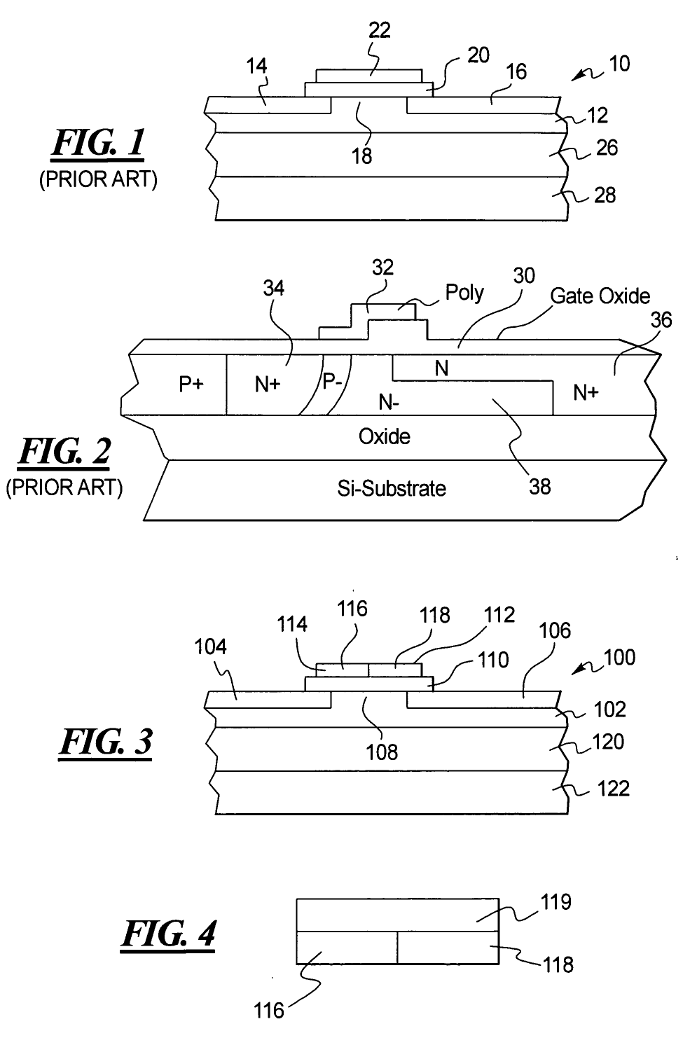

### DETAILED DESCRIPTION

A transistor 100 in accordance with an embodiment of the present invention is shown in FIG. 3. The transistor 100 includes a silicon layer 102 that is doped to form a source region 104 and a drain region 106 separated by a channel region 108. A gate oxide 110, which can be either thermally grown oxide or a deposited high dielectric constant insulating layer, is deposited over the channel region 108. The gate oxide 110 may be formed either by thermal oxidation or by deposition such as LPCVD, plasma CVD, etc. A dual work function gate 112 is formed by suitably depositing a silicon layer 114, such as a polysilicon layer, over the gate oxide 110. A first gate region 116 of the silicon layer 114 is doped so that the first gate region 116 is an n+ region, and a second gate region 118 of the silicon layer 114 is doped so that the second gate region 118 is an p+ region. The transistor 100 may also include a buried oxide layer 120 over a silicon wafer 122, as desired.

During formation of the transistor 100, a portion (such as half) of the silicon layer 114 in the area of the gate 112 may be masked during implanting (doping) of the source and drain regions 104 and 106 because the unmasked portion (either the first gate region 116 or the second gate region 118) receives the same doping as the source and drain regions 104 and 106. Subsequently, the originally masked gate region may then be unmasked to receive its suitable doping.

Furthermore, the areas of the silicon layer 114 that are doped to form the n+ first gate region 116 and the p+ second gate region 118 may be selectively controlled depending upon the device that is being fabricated. Additionally, the gate 112 may be silicided to reduce resistance. FIG. 4 shows a resulting silicide region 119 formed over the first and second gate regions 116 and 118.

The breakdown voltage of the transistor 100 depends upon the doping of the source region 104 and the drain region 106. The thickness of the gate oxide 110 is also used to control the breakdown voltage of the transistor 100 such that the thickness of the gate oxide 110 is increased in order to increase the breakdown voltage of the transistor 10. Unlike the transistor 10, however, the transistor 100 has a higher breakdown voltage. The work function of the second gate region 118 may be on the order of 1.0 eV higher than the work function of the first gate region 116. Therefore, the additional potential barrier will be similar to the drain extension of an LDMOS and hence increases the breakdown voltage.

For proper operation of the transistor 100, the alignment between the gate 112, the gate oxide 110, the source region 104, the drain region 106, and the channel region 108 of the transistor 100 is similar to that of the transistor 10.

Furthermore, because n+ and p+ implants are used to form the first and second gate regions 116 and 118, multiple threshold CMOS devices can be implemented such that the p+ polysilicon can be used for a PMOS device, the p+ polysilicon can be used for an NMOS device, the n+ polysilicon can be used for an NMOS device, and the n+ polysilicon can be used for a PMOS device. Therefore, the transistor 100 can be used in applications requiring selective multiple turn on and turn off voltages. The threshold voltages are set by the work function of the gate and threshold implants.

Also, the doping of a polysilicon layer to form the dual work function gate provided by the first and second gate regions 116 and 118 can be implemented for p-MOS to achieve CMOS. Moreover, hot electron degradation, which is normally a problem in fabricating CMOS devices, is minimized, which leads to a minimization of drain induced barrier lowering (DIBL).

Certain modifications of the present invention will occur to those practicing in the art of the present invention. Other modifications will occur to those practicing in the art of the present invention. For example, the transistor 100 may be a CMOS, DMOS, CDMOS, PMOS, NMOS, Bi-CDMOS, or other semiconductor device.

Accordingly, the description of the present invention is to be construed as illustrative only and is for the purpose of teaching those skilled in the art the best mode of carrying out the invention. The details may be varied substantially without departing from the spirit of the invention, and the exclusive use of all modifications which are within the scope of the appended claims is reserved.

1. A transistor comprising:
a first silicon layer having a source region and a drain region separated by a channel region;
a gate oxide formed over the first silicon layer; and,
a second silicon layer formed over the gate oxide, wherein the second silicon layer includes a dual work function gate that provides the transistor with at least first and second voltage thresholds.

2. The transistor of claim 1 wherein the second silicon layer comprises a polysilicon layer.

3. The transistor of claim 2 wherein the polysilicon layer comprises a p+ gate region and an n+ gate region forming the dual work function gate.

4. The transistor of claim 1 wherein the dual work function gate comprises a p+ gate region and an n+ gate region formed in the second silicon layer.

5-9. (canceled)

10. A semiconductor device comprising:
a first silicon layer having first and second electrodes formed therein;
a gate oxide formed over the first silicon layer; and,
a second silicon layer formed over the gate oxide, wherein the second silicon layer comprises a dual work function gate having differently doped regions of substantially equal areas.

11. The semiconductor device of claim 10 wherein the second silicon layer comprises a polysilicon layer.

12. The semiconductor device of claim 11 wherein the polysilicon layer comprises a p+ gate region and an n+ gate region forming the dual work function gate.

13. The semiconductor device of claim 10 wherein the dual work function gate comprises a p+ gate region and an n+ gate region formed in the second silicon layer.

14-18. (canceled)

19. A method of making a transistor comprising:
forming a buried oxide layer over a first silicon layer;
forming a second silicon layer over the buried oxide layer such that the second silicon layer includes a source region and a drain region separated by a channel region;
forming a gate oxide formed over the channel region of the second silicon layer; and,
forming a third silicon layer over the gate oxide such that the third silicon layer includes a dual work function gate having regions of differing conductivity.

20. The method of claim 19 wherein the third silicon layer comprises a polysilicon layer.

21. The method of claim 20 wherein the polysilicon layer comprises a p+ gate region and an n+ gate region forming the dual work function gate.

22. The method of claim 19 wherein the dual work function gate comprises a p+ gate region and an n+ gate region formed in the third silicon layer.

23. (canceled)

24. The transistor of claim 1 wherein the dual work function gate comprises first and second gate regions having different conductivities.

25. The transistor of claim 1 wherein the dual work function gate comprises first and second gate regions having different conductivities, wherein the first and second gate regions each has a lateral dimension and a transverse dimension, wherein the lateral dimension extends parallel to the source and drain regions, wherein the transverse dimension extends perpendicularly to the source and drain regions, and wherein the lateral dimension is greater than the transverse dimension.

26. The semiconductor device of claim 10 wherein the dual work function gate comprises first and second gate regions having different conductivities.

27. The semiconductor device of claim 10 wherein the dual work function gate comprises first and second gate regions having different conductivities, wherein the first and second gate regions each has a lateral dimension and a transverse dimension, wherein the lateral dimension extends parallel to the source and drain regions, wherein the transverse dimension extends perpendicularly to the source and drain regions, and wherein the lateral dimension is greater than the transverse dimension.

28. The method of claim 19 wherein the forming of a third silicon layer comprises forming the third silicon layer so that the first and second gate regions are substantially coextensive.

29. The method of claim 19 wherein the forming of a third silicon layer comprises forming the third silicon layer so that so that the dual work function gate comprises first and second gate regions, so that the first and second gate regions each has a lateral dimension and a transverse dimension, so that the lateral dimension extends parallel to the source and drain regions, so that the transverse dimension extends perpendicularly to the source and drain regions, and so that the lateral dimension is greater than the transverse dimension.

30. A transistor comprising:
a first silicon layer having a source region and a drain region separated by a channel region;
a gate oxide formed over the channel region of the first silicon layer; and,
a second silicon layer formed over the gate oxide, wherein the second silicon layer includes a dual work function gate comprising first and second gate regions, wherein the first and second gate regions each has a lateral dimension and a transverse dimension, wherein the lateral dimension extends parallel to the source and drain regions, wherein the transverse dimension extends perpendicularly to the source and drain regions, and wherein the lateral dimension is greater than the transverse dimension.

31. The transistor of claim 30 wherein the second silicon layer comprises a polysilicon layer.

32. The transistor of claim 31 wherein the first gate region comprises a p+ gate region, and wherein the second gate region comprises an n+ gate region.

33. The transistor of claim 30 wherein the first gate region comprises a p+ gate region, and wherein the second gate region comprises an n+ gate region.
